(19) United States
(12) Patent Application Publication
(10) Pub. No.: US 2026/0331870 A1
(43) Pub. Date: Oct. 22, 2026

(54) WAVELENGTH TUNABLE LASERS BASED ON SILICON SEMICONDUCTORS AND III-V COMPOUND SEMICONDUCTORS

(71) Applicant: Korea Advanced Institute of Science and Technology, Daejeon (KR)

(72) Inventors: Sanghyeon Kim, Daejeon (KR); Shin Hyung Lee, Daejeon (KR); Dong Gil Kang, Daejeon (KR)

(21) Appl. No.: 19/573,832

(22) Filed: Mar. 20, 2026

(30) Foreign Application Priority Data
Apr. 22, 2025 (KR) 10-2025-0052214

(51) Int. Cl. H01S 5/14; H01S 5/026; H01S 5/042

(52) U.S. Cl. CPC H01S 5/142; H01S 5/026; H01S 5/04252

(57) ABSTRACT

A wavelength tunable laser based on a silicon semiconductor and a group III-V compound semiconductor according to one embodiment of the present disclosure includes a base member, a optical gain unit, and a filter unit. The optical gain unit is disposed on the base member. The optical gain unit may emit or amplify light. The filter unit is disposed on the base member. The filter unit includes a ring resonator having a predetermined resonant frequency. The filter unit reflects light having the predetermined resonant frequency among received light in a direction toward the optical gain unit. A filter-unit modulator includes a first filter-unit semiconductor, a second filter-unit semiconductor, and a filter-unit insulator. The filter-unit semiconductor includes a P-type silicon semiconductor. The second filter-unit semiconductor is disposed above the first filter-unit semiconductor. The second filter-unit semiconductor includes an N-type group III-V compound semiconductor. The filter-unit insulator is disposed between the first filter-unit semiconductor and the second filter-unit semiconductor. The filter unit insulator includes an insulating material.

### CROSS-REFERENCE TO RELATED APPLICATION

The present application claims priority to and the benefit of Korean Patent Application No. 10-2025-0052214, filed on Apr. 22, 2025, in the Korean Intellectual Property Office, and all the benefits accruing therefrom under 35 U.S. C § 119, the contents of which are incorporated herein in its entirety by reference.

### BACKGROUND

### 1. Field

The present disclosure relates to a wavelength tunable laser. Particularly, the present disclosure relates to a wavelength tunable laser based on a silicon semiconductor and a group III-V compound semiconductor.

### 2. Description of the Related Art

In order to advance a Lidar system, a wavelength tunable laser is essential. Particularly, by using a wavelength tunable laser, the system may support multiple channels, and the accuracy of distance and velocity measurements may be significantly improved.

To implement a wavelength tunable laser, approaches, such as a thermo-optic method, and an electro-optic method, have been used. The thermo-optic method is a technique of controlling a wavelength of light by adjusting characteristics of a resonator or waveguide based on the principle that a refractive index changes with temperature. The electro-optic method is a technique of controlling a wavelength of light by controlling a refractive index of a material through application of an electric field.

When a wavelength tunable laser is implemented using the thermo-optic method, there is a challenge in a limited wavelength modulation speed. When a wavelength tunable laser is implemented using only silicon semiconductors based on the electro-optic method, there is a challenge in high optical loss and large power consumption during wavelength modulation.

### SUMMARY

The present disclosure is to resolve conventional problems as described above. The present disclosure is to provide a wavelength tunable laser having a silicon semiconductor and a group III-V compound semiconductor disposed in a Semiconductor Insulator Semiconductor (SIS) structure to allow precise and high-speed control of a wavelength of emitted light and amplification of intensity of the emitted light.

A wavelength tunable laser based on a silicon semiconductor and a group III-V compound semiconductor according to one embodiment of the present disclosure may include a base member, a optical gain unit, and a filter unit. The optical gain unit may be disposed on the base member. The optical gain unit may emit or amplify light. The filter unit may be disposed on the base member. The filter unit may include a ring resonator having a predetermined resonant frequency. The filter unit may reflect light having the predetermined resonant frequency among received light in a direction toward the optical gain unit. The ring resonator may include a filter-unit modulator. The filter-unit modulator may modify the predetermined resonant frequency. The filter-unit modulator may include a first filter-unit semiconductor, a second filter-unit semiconductor, and a filter-unit insulator. The first filter-unit semiconductor may include a P-type silicon semiconductor. The second filter-unit semiconductor may be disposed above the first filter-unit semiconductor. The second filter-unit semiconductor may include an N-type group III-V compound semiconductor. The filter-unit insulator may be disposed between the first filter-unit semiconductor and the second filter-unit semiconductor. The filter-unit insulator may include an insulating material.

A wavelength tunable laser based on a silicon semiconductor and a group III-V compound semiconductor according to one embodiment of the present disclosure may further include a reflection unit disposed on the base member. The reflection unit may reflect at least a portion of received light in a direction towards the optical gain unit and output a remaining portion to outside. The optical gain unit may be disposed between the reflection unit and the filter unit.

A wavelength tunable laser based on a silicon semiconductor and a group III-V compound semiconductor according to one embodiment of the present disclosure may further include a phase modulation unit disposed on the base member. An optical path, through which light may propagate, may be defined between the filter unit and the reflection unit. The phase modulation unit may modify a resonant frequency of the optical path.

In one embodiment of the present disclosure, the phase modulation unit may be disposed between the optical gain unit and the filter unit. The phase modulation unit may include a first modulation-unit semiconductor, a second modulation-unit semiconductor, and a modulation-unit insulator. The first modulation-unit semiconductor may include a P-type silicon semiconductor. The second modulation-unit semiconductor may be disposed above the first modulation-unit semiconductor. The second modulation-unit semiconductor may include an N-type group III-V compound semiconductor. The modulation-unit insulator may be disposed between the first modulation-unit semiconductor and the second modulation-unit semiconductor. The modulation-unit insulator may include an insulating material.

In one embodiment of the present disclosure, the filter-unit modulator may further include a first filter-unit electrode and a second filter-unit electrode. The first filter-unit electrode may make contact with the first filter-unit semiconductor. The second filter-unit electrode may make contact with the second filter-unit semiconductor. The phase modulation unit may further include a first modulation-unit electrode and a second modulation-unit electrode. The first modulation-unit electrode may make contact with the first modulation-unit semiconductor. The second modulation-unit electrode may make contact with the second modulation-unit semiconductor.

In one embodiment of the present disclosure, the optical gain unit may include a first optical-gain-unit semiconductor, a second optical-gain-unit semiconductor, and a light-emission layer. The first optical-gain-unit semiconductor may include an N-type group III-V compound semiconductor. The second optical-gain-unit semiconductor may face the first optical-gain-unit semiconductor and include a P-type silicon semiconductor. The light-emission layer may be disposed between the first optical-gain-unit semiconductor and the second optical-gain-unit semiconductor. The light-emission layer may emit light. The first optical-gain-unit semiconductor may be disposed on a layer different from at least one of the second filter-unit semiconductor and the second modulation-unit semiconductor.

A wavelength tunable laser based on a silicon semiconductor and a group III-V compound semiconductor according to one embodiment of the present disclosure may further include a bonding member including an insulating material. At least any one of the second filter-unit semiconductor and the second modulation-unit semiconductor may be disposed below the bonding member. The first optical-gain-unit semiconductor may be disposed above the bonding member.

In one embodiment of the present disclosure, the base member may include SiO2. The group III-V compound semiconductor may include at least any one of InP, InGaAsP, and InGaAlAs. Each of the first filter-unit electrode, the second filter-unit electrode, the first modulation-unit electrode, and the second modulation-unit electrode may include at least any one of Pt, Ti, Au, TiN, Al, W, Ag, Cu, Au, Ge, and Ni.

In one embodiment of the present disclosure, the reflection unit may have a first area and a second area defined therein. A thickness of the reflection unit measured in the first area may be greater than a thickness of the reflection unit measured in the second area.

In one embodiment of the present disclosure, the ring resonator may be provided in a plurality. The plurality of ring resonators may have different resonant frequencies from one another. The filter unit may further include at least any one of a multimode interferometer and a mirror. The multimode interferometer may split received light or combine received light. The mirror may reflect at least a portion of received light.

A wavelength tunable laser based on a silicon semiconductor and a group III-V compound semiconductor according to one embodiment of the present disclosure may include a base member, a optical gain unit, a filter unit, and a reflection unit. The optical gain unit may be disposed on the base member. The optical gain unit may emit or amplify light. The filter unit may be disposed on the base member. The filter unit may include a ring resonator having a predetermined resonant frequency. The filter unit may reflect light having the predetermined resonant frequency among received light in a direction toward the optical gain unit. The reflection unit may be disposed on the base member. The reflection unit may reflect at least a portion of received light in a direction toward the optical gain unit and output a remaining portion to outside. The ring resonator may include a filter-unit modulator configured to modify the predetermined resonant frequency. The filter-unit modulator may have a Semiconductor Insulator Semiconductor (SIS) structure, in which an insulator is disposed between two semiconductors.

A wavelength tunable laser based on a silicon semiconductor and a group III-V compound semiconductor according to one embodiment of the present disclosure may further include a phase modulation unit disposed on the base member. An optical path, through which light may propagate, may be defined between the filter unit and the reflection unit. The phase modulation unit may modify a resonant frequency of the optical path.

In one embodiment of the present disclosure, the filter-unit modulator may include a first filter-unit semiconductor, a second filter-unit semiconductor, and a filter-unit insulator. The first filter-unit semiconductor may include a P-type silicon semiconductor. The second filter-unit semiconductor may be disposed above the first filter-unit semiconductor. The second filter-unit semiconductor may include an N-type group III-V compound semiconductor. The filter-unit insulator may be disposed between the first filter-unit semiconductor and the second filter-unit semiconductor. The filter-unit insulator may include an insulating material.

In one embodiment of the present disclosure, the phase modulation unit may include a first modulation-unit semiconductor, a second modulation-unit semiconductor, and a modulation-unit insulator. The first modulation-unit semiconductor may include a P-type silicon semiconductor. The second modulation-unit semiconductor may be disposed above the first modulation-unit semiconductor. The second modulation-unit semiconductor may include an N-type group III-V compound semiconductor. The modulation-unit insulator may be disposed between the first modulation-unit semiconductor and the second modulation-unit semiconductor. The modulation-unit insulator may include an insulating material.

In one embodiment of the present disclosure, the filter-unit modulator may further include a first filter-unit electrode and a second filter-unit electrode. The first filter-unit electrode may make contact with the first filter-unit semiconductor. The second filter-unit electrode may make contact with the second filter-unit semiconductor. The phase modulation unit may further include a first modulation-unit electrode and a second modulation-unit electrode. The first modulation-unit electrode may make contact with the first modulation-unit semiconductor. The second modulation-unit electrode may make contact with the second modulation-unit semiconductor.

In one embodiment of the present disclosure, the optical gain unit may include a first optical-gain-unit semiconductor, a second optical-gain-unit semiconductor, and a light-emission layer. The first optical-gain-unit semiconductor may include an N-type group III-V compound semiconductor. The second optical-gain-unit semiconductor may face the first optical-gain-unit semiconductor and include a P-type silicon semiconductor. The light-emission layer may be disposed between the first optical-gain-unit semiconductor and the second optical-gain-unit semiconductor. The light-emission layer may emit light. The first optical-gain-unit semiconductor may be disposed on a layer different from at least one of the second filter-unit semiconductor and the second modulation-unit semiconductor.

A wavelength tunable laser based on a silicon semiconductor and a group III-V compound semiconductor according to one embodiment of the present disclosure may further include a bonding member including an insulating material. At least any one of the second filter-unit semiconductor and the second modulation-unit semiconductor may be disposed below the bonding member. The first optical-gain-unit semiconductor may be disposed above the bonding member.

In one embodiment of the present disclosure, the base member may include SiO2. The group III-V compound semiconductor may include at least any one of InP, InGaAsP, and InGaAlAs. Each of the first filter-unit electrode, the second filter-unit electrode, the first modulation-unit electrode, and the second modulation-unit electrode may include at least any one of Pt, Ti, Au, TiN, Al, W, Ag, Cu, Au, Ge, and Ni.

In one embodiment of the present disclosure, the reflection unit may have a first area and a second area defined therein. A thickness of the reflection unit measured in the first area may be greater than a thickness of the reflection unit measured in the second area.

In one embodiment of the present disclosure, the ring resonator may be provided in a plurality. The plurality of ring resonators may have different resonant frequencies from one another. The filter unit may further include at least any one of a multimode interferometer and a mirror. The multimode interferometer may split received light or combine received light. The mirror may reflect at least a portion of received light.

According to one embodiment of the present disclosure, the present disclosure is to resolve conventional problems as described above, and the present disclosure may provide a wavelength tunable laser having a silicon semiconductor and a group III-V compound semiconductor disposed in a Semiconductor Insulator Semiconductor (SIS) structure to allow precise and high-speed control of a wavelength of emitted light and amplification of intensity of the emitted light.

### BRIEF DESCRIPTION OF THE DRAWINGS

The accompanying drawings are included to provide a further understanding of the present disclosure and are incorporated in and constitute a part of this disclosure. The drawings illustrate embodiments of the present disclosure and, together with the description, serve to explain principles of the disclosure. These and/or other features will become apparent and more readily appreciated from the following description of one or more embodiments, taken in conjunction with the accompanying drawings, in which:

FIG. 1A is an exemplary perspective view of a Lidar system according to one embodiment of the present disclosure;

FIG. 1B is an exemplary perspective view of a wavelength tunable laser based on a silicon semiconductor and a group III-V compound semiconductor according to one embodiment of the present disclosure;

FIG. 1C and FIG. 1D are graphs showing respective optical characteristics of a plurality of ring resonators and a wavelength tunable laser based on a silicon semiconductor and a group III-V compound semiconductor with respect to frequency;

FIG. 2A is an enlarged view of the filter unit shown in FIG. 1B;

FIG. 2B is an exemplary cross-sectional view taken along the I-I′ line shown in FIG. 2A;

FIG. 3A and FIG. 3B are exemplary cross-sectional views of a filter-unit modulator according to one embodiment of the present disclosure;

FIG. 4A is an enlarged view of the phase modulation unit shown in FIG. 1B;

FIG. 4B is an exemplary cross-sectional view taken along the II-II′ line shown in FIG. 4A;

FIG. 5A and FIG. 5B are exemplary cross-sectional views of a phase modulation unit according to another embodiment of the present disclosure;

FIG. 6A is an enlarged view of the reflection unit shown in FIG. 1B;

FIG. 6B is an exemplary cross-sectional view taken along the III-III′ shown in FIG. 6A;

FIG. 7 is an exemplary cross-sectional view of a reflection unit according to another embodiment of the present disclosure;

FIG. 8 is an exemplary cross-sectional view of a optical gain unit according to one embodiment of the present disclosure;

FIG. 9 is an exemplary cross-sectional view of a portion of a wavelength tunable laser based on a silicon semiconductor and a group III-V compound semiconductor according to one embodiment of the present disclosure;

FIG. 10 is an exemplary cross-sectional view of a portion of a wavelength tunable laser based on a silicon semiconductor and a group III-V compound semiconductor according to another embodiment of the present disclosure;

FIG. 11A and FIG. 11B are exemplary illustrations of shapes of filter units according to one embodiment of the present disclosure;

FIG. 12 is an exemplary illustration of a mirror according to one embodiment of the present disclosure; and

FIG. 13A and FIG. 13B are exemplary illustrations of shapes of filter units according to one embodiment of the present disclosure.

### DETAILED DESCRIPTION

References will now be made in detail to certain embodiments, of which examples are illustrated in the accompanying drawings, where like reference numerals refer to like elements throughout. The embodiments may have a variety of forms and permutations, but the present disclosure shall by no means be construed as being limited to the described embodiments. Rather, the present disclosure shall be construed to encompass all forms, permutations, equivalents and substitutes covered by the technical ideas and scope of the present disclosure. Accordingly, the embodiments are merely described below, by referring to the figures, to explain features of the present disclosure.

Hereinafter, certain embodiments of the present disclosure will be described in more detail with reference to the accompanying drawings. In the drawings, the proportions and dimensions of components may be exaggerated for clarity and ease of explanation.

Any expressions such as “comprise” or “include” are intended to specify the presence of features, integers, steps, operations, elements, components, or combinations thereof stated in the specification, and shall not be construed to preclude any possibility of presence or addition of one or more other features, integers, steps, operations, elements, components, or combinations thereof.

Furthermore, when a component is described as being “on” another component, it may be located above or below the other component and does not necessarily imply being positioned on the upper side in the direction of gravity.

When a component is described as being “connected” to another component or “combined with received light”, it may be directly connected to the other component or combined with received light or indirectly connected or combined with received light via another component.

Terms such as “first” and “second” may be used when referring to components, but these terms are intended only for distinguishing one component from another and do not imply any limitation on the nature, order, or sequence of the components.

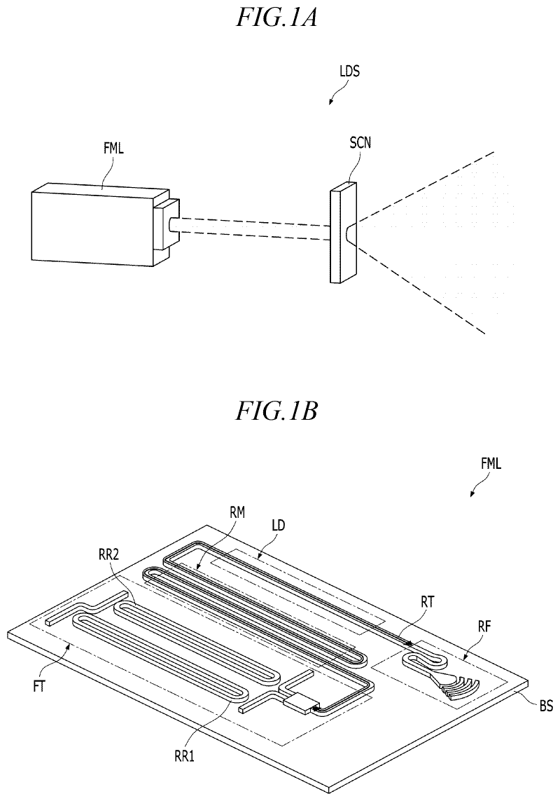

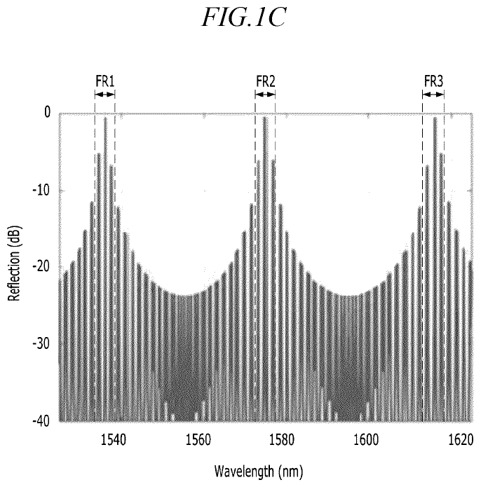

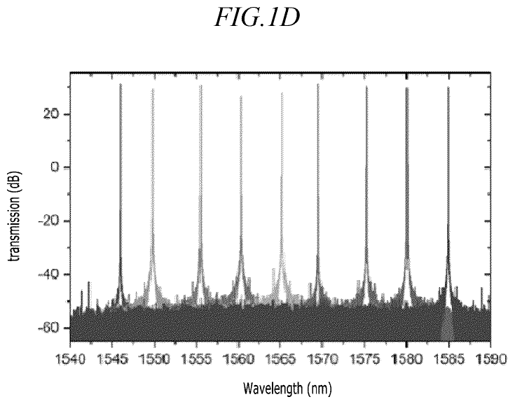

FIG. 1A is an exemplary perspective view of a Lidar system LDS according to one embodiment of the present disclosure.

FIG. 1B is an exemplary perspective view of a wavelength tunable laser FML based on a silicon semiconductor and a group III-V compound semiconductor according to one embodiment of the present disclosure.

FIG. 1C and FIG. 1D are graphs showing respective optical characteristics of a plurality of ring resonators RR and a wavelength tunable laser FML based on a silicon semiconductor and a group III-V compound semiconductor with respect to frequency.

Referring to FIG. 1A, a Lidar system LDS according to one embodiment of the present disclosure may include a wavelength tunable laser FML based on a silicon semiconductor and a group III-V compound semiconductor, and a scanner SCN.

The wavelength tunable laser FML based on a silicon semiconductor and a group III-V compound semiconductor emits a laser beam and modifies a wavelength of the emitted laser beam.

The scanner SCN may rapidly propagate the laser beam emitted from the wavelength tunable laser FML based on a silicon semiconductor and a group III-V compound semiconductor in various directions to scan a wide area.

Referring to FIG. 1B, the wavelength tunable laser FML based on a silicon semiconductor and a group III-V compound semiconductor according to one embodiment of the present disclosure may include at least any one of a base member BS, a optical gain unit LD, a filter unit FT, a phase modulation unit RM, and a reflection unit RF.

The base member BS may support the optical gain unit LD, the filter unit FT, the phase modulation unit RM, and the reflection unit RF. For example, the base member BS may include SiO2.

The optical gain unit LD may be disposed on the base member BS. The optical gain unit LD may emit or amplify light. The optical gain unit LD may be disposed between the reflection unit RF and the phase modulation unit RM.

The filter unit FT may include a ring resonator RR. The filter unit FT may be disposed on the base member BS.

Referring to FIG. 1C, the filter unit FT may reflect light having a resonant frequency of the ring resonator RR among received light in a direction toward the optical gain unit LD. In one embodiment of the present disclosure, the ring resonator RR may be provided in a plurality, and the plurality of ring resonators may have different resonant frequencies.

The filter unit FT may reflect light having a first resonant frequency FR1, light having a second resonant frequency FR2, and light having a third resonant frequency FR3 in a direction toward the optical gain unit LD. The optical gain unit LD may amplify any one of the light having a first resonant frequency FR1, the light having a second resonant frequency FR2, and the light having a third resonant frequency FR3. For example, the optical gain unit LD may amplify the light having a second resonant frequency FR2.

The phase modulation unit RM may be disposed on the base member BS. In one embodiment of the present disclosure, the phase modulation unit RM may be disposed between the optical gain unit LD and the filter unit FT.

An optical path RT through which light may propagate may be defined between the filter unit FT and the reflection unit RF. The phase modulation unit RM may modify a resonant frequency of the optical path RT. Among light propagated along the optical path RT, light that does not have the resonant frequency of the optical path RT may be scattered or absorbed. As a result, only light having the resonant frequency of the optical path RT may remain.

The ring resonator RR may have a structure, such as Rib without Isolation Etch, and Rib with Isolation Etch.

In case that the ring resonator RR has a Rib without Isolation Etch structure, there may exist an area around the Rib that is not fully etched. Accordingly, light may propagate over a wide area.

In case that the ring resonator RR has a Rib with Isolation Etch structure, an area around the Rib is deeply etched, allowing light to be focused inside the Rib. In addition, in case that the ring resonator RR has a Rib with Isolation Etch structure, a parasitic capacitance that may occur in a Semiconductor Insulator Semiconductor (SIS) structure may be reduced.

In case that the ring resonator RR has a Ledge structure, an area except for a portion of a side of the Rib may be deeply etched. Accordingly, a wide area may be secured for electrode disposition.

Referring to FIG. 1D, a wavelength tunable laser FML based on a silicon semiconductor and a group III-V compound semiconductor according to one embodiment of the present disclosure may selectively emit light having a certain wavelength.

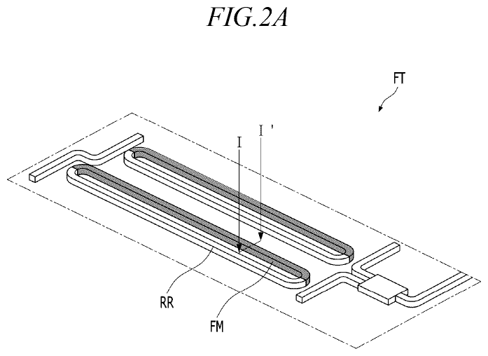

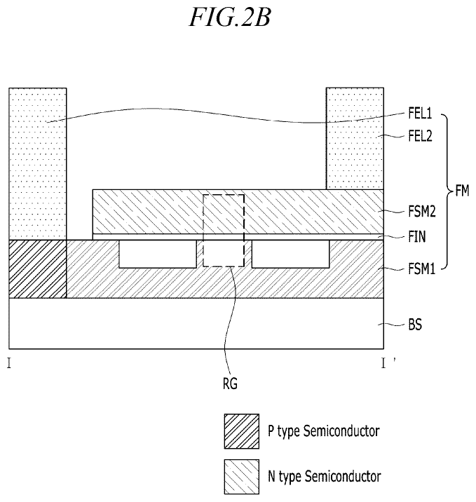

FIG. 2A is an enlarged view of the filter unit FT shown in FIG. 1B.

FIG. 2B is an exemplary cross-sectional view taken along the I-I′ line shown in FIG. 2A.

Referring to FIG. 2A, the ring resonator RR may include a filter unit modulator FM.

Referring to FIG. 2B, a partial area RG of the filter-unit modulator FM may function as a waveguide, and the filter-unit modulator FM may have a Rib without Isolation Etch structure. The filter-unit modulator FM may modify a resonant frequency of the ring resonator RR.

In one embodiment of the present disclosure, the filter-unit modulator FM may have a Semiconductor Insulator Semiconductor (SIS) structure. The Semiconductor Insulator Semiconductor (SIS) structure may be a structure in which an insulator FIN is disposed between two semiconductors FSM1, FSM2.

The filter-unit modulator FM may include at least any one of a first filter-unit semiconductor FSM1, a second filter-unit semiconductor FSM2, a filter-unit insulator FIN, a first filter-unit electrode FEL1, and a second filter-unit electrode Fel2.

In the present disclosure, the P-type silicon semiconductor refers to a P-type semiconductor based on silicon, and the N-type group III-V compound semiconductor refers to an N-type semiconductor based on a group III-V compound.

The first filter-unit semiconductor FSM1 may include a P-type silicon semiconductor. A silicon photonic integrated circuit may be formed on the first filter-unit semiconductor FSM1.

The second filter-unit semiconductor FSM2 may be disposed above the first filter-unit semiconductor FSM1. The second filter-unit semiconductor FSM2 may include an N-type group III-V compound semiconductor. For example, the group III-V compound semiconductor may include at least any one of InP, InGaAsP, and InGaAlAs.

The filter-unit insulator FIN may be disposed between the first filter-unit semiconductor FSM1 and the second filter-unit semiconductor FSM2. The filter-unit insulator FIN may include an insulating material. For example, the insulating material may include at least any one of SiO2, Al2O3, Y2O3, and HfO2. However, these are merely examples, and the insulating material of the present disclosure is not limited hereto. A material having a high dielectric constant is sufficient as an insulating material of the present disclosure.

The first filter-unit electrode FEL1 may make contact with at least a portion of the first filter-unit semiconductor FSM1. For example, the first filter-unit electrode Fel1 may include at least any one of Pt, Ti, Au, TiN, Al, W, Ag, Cu, Au, Ge, and Ni.

The second filter-unit electrode FEL2 may make contact with at least a portion of the second filter-unit semiconductor FSM2. For example, the second filter-unit electrode FEL2 may each include at least any one of Pt, Ti, Au, TiN, Al, W, Ag, Cu, Au, Ge, and Ni.

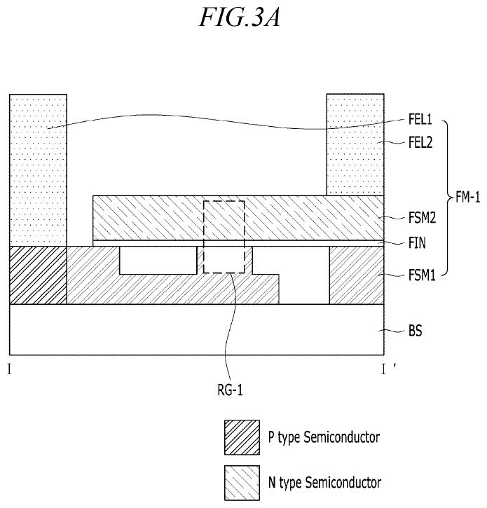

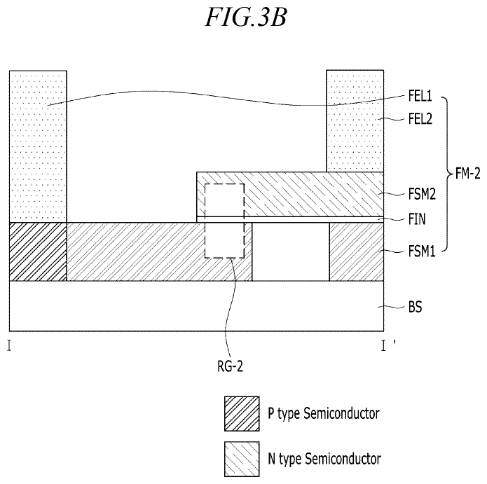

FIG. 3A and FIG. 3B are exemplary cross-sectional views of filter-unit modulators FM-1, FM-2 according to one embodiment of the present disclosure.

Referring to FIG. 3A, a partial area RG-1 of the filter-unit modulator FM-1 may function as a waveguide, and the filter-unit modulator FM-1 may have a Rib with Isolation Etch structure.

Referring to FIG. 3B, a partial area RG-2 of the filter-unit modulator FM-2 may function as a waveguide, and the filter-unit modulator FM-2 may have a Rib with Isolation Etch structure.

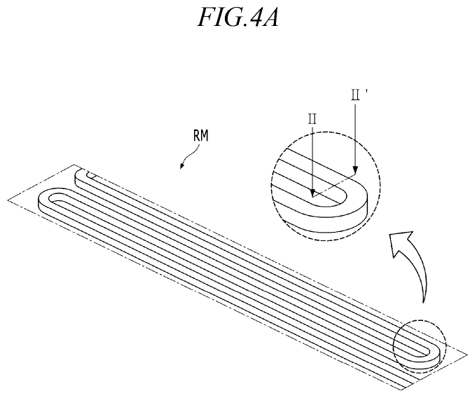

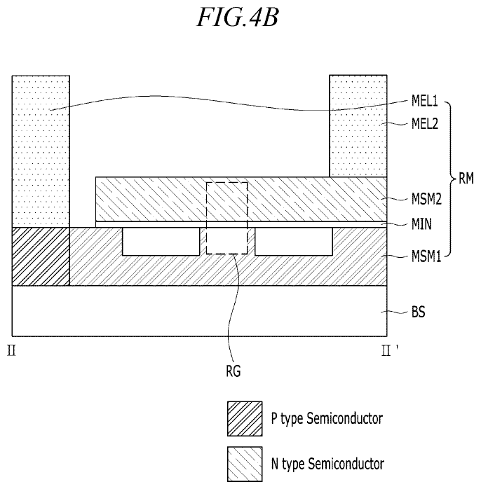

FIG. 4A is an enlarged view of the phase modulation unit RM shown in FIG. 1B.

FIG. 4B is an exemplary cross-sectional view taken along the II-II′ shown in FIG. 4A.

Referring to FIG. 4A and FIG. 4B, the phase modulation unit RM may include at least any one of a first modulation-unit semiconductor MSM1, a second modulation-unit semiconductor MSM2, a modulation-unit insulator MIN, a first modulation-unit electrode MEL1, and a second modulation-unit electrode Mel2. The phase modulation unit RM may be disposed between the optical gain unit LD and the filter unit FT.

The first modulation-unit semiconductor MSM1 may include a P-type silicon semiconductor. A silicon photonic integrated circuit may be formed on the first modulation-unit semiconductor MSM1

The second modulation-unit semiconductor MSM2 may be disposed above the first modulation-unit semiconductor MSM1. The second modulation-unit semiconductor MSM2 may include an N-type group III-V compound semiconductor. For example, the group III-V compound semiconductor may include at least any one of InP, InGaAsP, and InGaAlAs.

The modulation-unit insulator MIN may be disposed between the first modulation-unit semiconductor MSM1 and the second modulation-unit semiconductor MSM2. The modulation-unit insulator MIN may include an insulating material. For example, the insulating material may include at least any one of SiO2, Al2O3, Y2O3, and HfO2. However, these are merely examples, and the insulating material is not limited thereto. A material having a high dielectric constant is sufficient as the insulating material of the present disclosure.

The first modulation-unit electrode MEL1 may make contact with at least a portion of the first modulation-unit semiconductor MSM1. For example, the first modulation-unit electrode MEL1 may include at least any one of Pt, Ti, Au, TiN, Al, W, Ag, Cu, Au, Ge, and Ni.

The second modulation-unit electrode MEL2 may make contact with at least a portion of the second modulation-unit semiconductor MSM2. For example, the second modulation-unit electrode MEL2 may include at least any one of Pt, Ti, Au, TiN, Al, W, Ag, Cu, Au, Ge, and Ni.

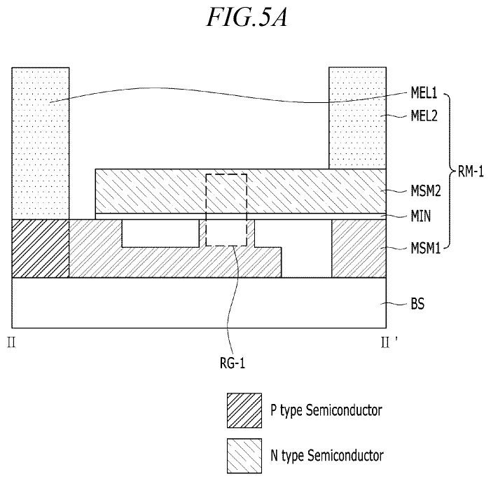

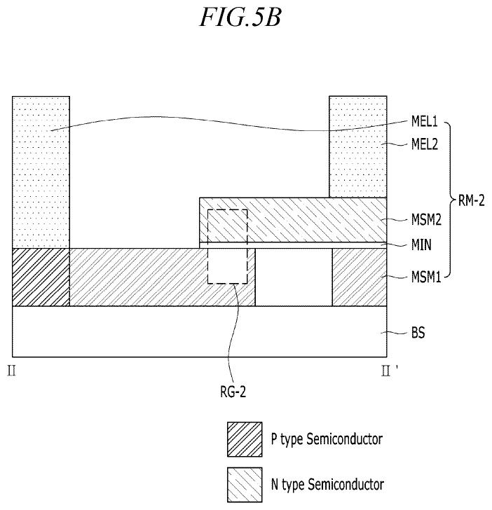

FIG. 5A and FIG. 5B are exemplary cross-sectional views of phase modulation units RM-1 RM-2 according to another embodiment of the present disclosure.

Referring to FIG. 5A, a partial area RG-1 of the phase modulation unit RM-1 may function as a waveguide, and the phase modulation unit RM-1 may have a Rib with Isolation Etch structure.

Referring to FIG. 5B, a partial area RG-2 of the phase modulation unit RM-2 may function as a waveguide, and the phase modulation unit RM-2 may have a Rib with Isolation Etch structure.

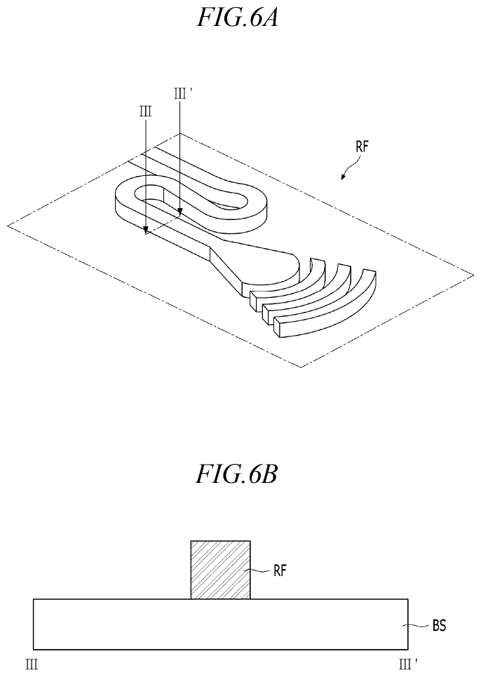

FIG. 6A is an enlarged view of the reflection unit RF shown in FIG. 1B.

FIG. 6B is an exemplary cross-sectional view taken along the III-III′ shown in FIG. 6A.

Referring to FIG. 6A and FIG. 6B, the reflection unit RF may reflect at least a portion of received light in a direction toward the optical gain unit LD and output a remaining portion to outside. The reflection unit RF may be disposed on the base member BS. For example, the reflection unit RF may include at least any one of Waveguide Coupler, MMI, and Bragg grating.

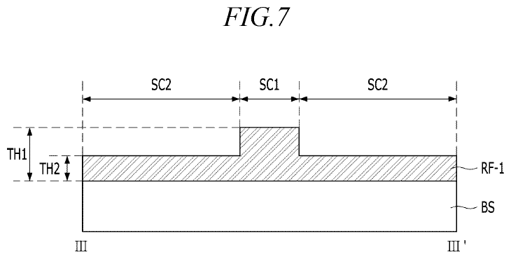

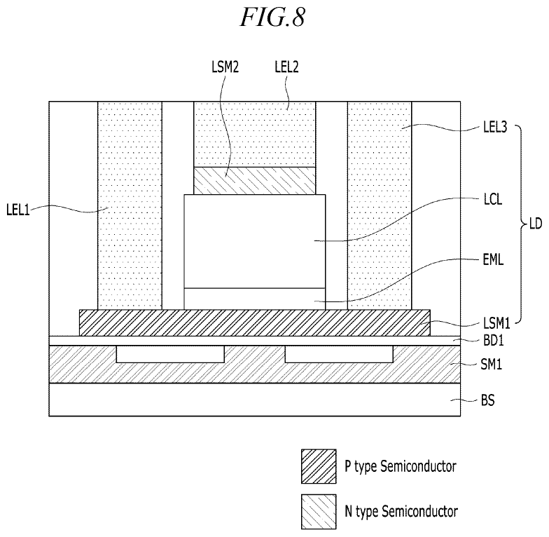

FIG. 7 is an exemplary cross-sectional view of a reflection unit RF-1 according to another embodiment of the present disclosure.

Referring to FIG. 7, the reflection unit RF-1 may have a first area SC1 and a second area SC2 defined therein. A first thickness TH1 of the reflection unit measured in the first area SC1 may be greater than a second thickness TH2 of the reflection unit measured in the second area SC2.

FIG. 8 is an exemplary cross-sectional view of the optical gain unit LD according to one embodiment of the present disclosure.

Referring to FIG. 8, a wavelength tunable laser FML based on a silicon semiconductor and a group III-V compound semiconductor according to one embodiment of the present disclosure may include a base member BS, a first semiconductor pattern SM1, a first bonding member BD1, a optical gain unit LD.

The base member BS may support the first semiconductor pattern SM1, the first bonding member BD1, and the optical gain unit LD.

A silicon photonic integrated circuit may be formed on the first semiconductor pattern SM1. The first semiconductor pattern SM1 may include silicon and a P-type silicon semiconductor. The first filter-unit semiconductor FSM1 (see FIG. 2B) and the first modulation-unit semiconductor MSM1 (see FIG. 4B) may each be a part of the first semiconductor pattern SM1.

The first bonding member BD1 may include an insulating material. The first bonding member BD1 may bond the first semiconductor pattern SM1 to the first optical-gain-unit semiconductor LSM1. The filter-unit insulator FIN (see FIG. 2B) and the modulation-unit insulator MIN (see FIG. 4B) may each be a part of the first bonding member BD1. For example, the insulating material may include at least any one of SiO2, Al2O3, Y2O3, and HfO2. However, these are merely examples, and the insulating material of the present disclosure is not limited thereto. A material having a high dielectric constant is sufficient as the insulating material of the present disclosure.

The optical gain unit LD may be disposed on the first bonding member BD1. The optical gain unit LD may include at least any one of a first optical-gain-unit semiconductor LSM1, a second optical-gain-unit semiconductor LSM2, a light-emission layer EML, a optical-gain-unit cladding LCL, a first optical-gain-unit electrode LEL1, a second optical-gain-unit electrode LEL2, and a third optical-gain-unit electrode LEL3. The optical gain unit LD may be disposed between the reflection unit RF and the filter unit FT.

The first optical-gain-unit semiconductor LSM1 may include an N-type group III-V compound semiconductor.

The second optical-gain-unit semiconductor LSM2 may face the first optical-gain-unit semiconductor LSM1 and include a P-type silicon semiconductor. The second optical-gain-unit semiconductor LSM2 may be disposed above the first optical-gain-unit semiconductor LSM1.

The light-emission layer EML may be disposed between the first optical-gain-unit semiconductor LSM1 and the second optical-gain-unit semiconductor LSM2. The light-emission layer EML may emit light.

The optical-gain-unit cladding LCL may be disposed between the light-emission layer EML and the second optical-gain-unit semiconductor LSM2.

The first optical-gain-unit electrode LEL1 may make contact with at least a portion of the first optical-gain-unit semiconductor LSM1. For example, the first optical-gain-unit electrode LEL1 may include at least any one of Pt, Ti, Au, TiN, Al, W, Ag, Cu, Au, Ge, and Ni.

The second optical-gain-unit electrode LEL2 may make contact with at least a portion of the second optical-gain-unit semiconductor LSM2. For example, the second optical-gain-unit electrode LEL2 may include at least any one of Pt, Ti, Au, TiN, Al, W, Ag, Cu, Au, Ge, and Ni.

The third optical-gain-unit electrode LEL3 may make contact with at least a portion of the first optical-gain-unit semiconductor LSM1. For example, the third optical-gain-unit electrode LEL3 may include at least any one of Pt, Ti, Au, TiN, Al, W, Ag, Cu, Au, Ge, and Ni.

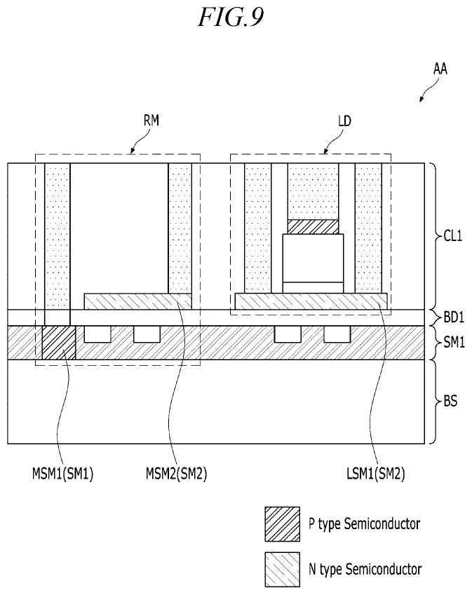

FIG. 9 is an exemplary cross-sectional view of a portion AA of a wavelength tunable laser FML based on a silicon semiconductor and a group III-V compound semiconductor according to one embodiment of the present disclosure.

Referring to FIG. 9, the wavelength tunable laser FML based on a silicon semiconductor and a group III-V compound semiconductor according to one embodiment of the present disclosure may include a base member BS, a first semiconductor pattern SM1, a first bonding member BD1, a second semiconductor pattern SM2, and a first cladding CL1.

At least any one of the filter-unit modulator FM, a phase modulation unit RM, and a optical gain unit LD may be disposed on the base member BS. The base member BS may support the first semiconductor pattern SM1, the first bonding member BD1, the second semiconductor pattern SM2, and the first cladding CL1.

A silicon photonic integrated circuit may be formed on the first semiconductor pattern SM1. The first semiconductor pattern SM1 may include silicon and a P-type silicon semiconductor. At least any one of the first filter-unit semiconductor FSM1 (see FIG. 2B), the first modulation-unit semiconductor MSM1 (see FIG. 4B), and the second optical-gain-unit semiconductor LSM2 (see FIG. 8) may be a part of the first semiconductor pattern SM1.

The first bonding member BD1 may include an insulating material. The first bonding member BD1 may bond the first semiconductor pattern SM1 to the second semiconductor pattern SM2. The filter-unit insulator FIN (see FIG. 2B) and the modulator insulator MIN (see FIG. 4B) may each be a part of the first bonding member BD1. For example, the insulating material may include at least any one of SiO2, Al2O3, Y2O3, and HfO2. However, these are merely examples, and the insulating material of the present disclosure is not limited thereto. A material having a high dielectric constant is sufficient as the insulating material of the present disclosure.

The second semiconductor pattern SM2 may include an N-type group III-V compound semiconductor. For example, the group III-V compound semiconductor may include at least any one of InP, InGaAsP, and InGaAlAs. The second filter-unit semiconductor FSM2 (see FIG. 2B) and the second modulation-unit semiconductor MSM2 (see FIG. 4B) may each be a part of the second semiconductor pattern SM2. The second filter-unit semiconductor FSM2 (see FIG. 2B) and the second modulation-unit semiconductor MSM2 (see FIG. 4B) may be formed through a same process.

The first cladding CL1 may have a low refractive index and focus light. The first cladding CL1 may cover at least a portion of each of the first bonding member BD1 and the second semiconductor pattern SM2. For example, the first cladding CL1 may include, for example, SiO2, or Polymer.

Referring to FIG. 9, the first optical-gain-unit semiconductor LSM1 may be disposed on a same layer as at least any one of the second filter-unit semiconductor FSM2 and the second modulation-unit semiconductor MSM2. Particularly, the first optical-gain-unit semiconductor LSM1, the second filter-unit semiconductor FSM2, and the second modulation-unit semiconductor MSM2 may be disposed on the first bonding member BD1.

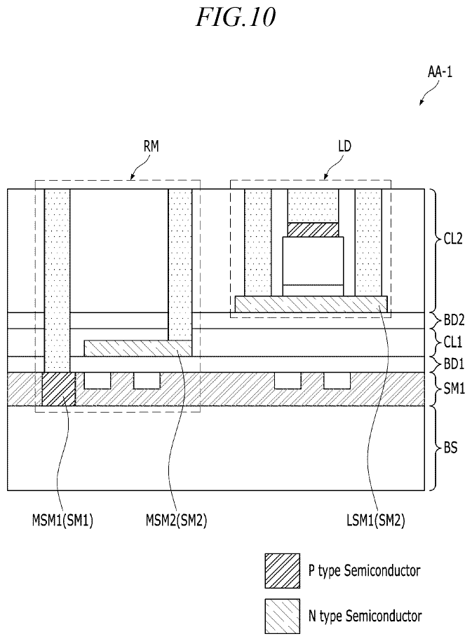

FIG. 10 is an exemplary cross-sectional view of a portion AA-1 of a wavelength tunable laser FML based on a silicon semiconductor and a group III-V compound semiconductor according to another embodiment of the present disclosure.

Referring to FIG. 10, the wavelength tunable laser FML based on a silicon semiconductor and a group III-V compound semiconductor may include a base member BS, a first semiconductor pattern SM1, a first bonding member BD1, a second semiconductor pattern SM2, a first cladding CL1, a second bonding member BD2, and a second cladding CL2.

The base member BS may support the first semiconductor pattern SM1, the first bonding member BD1, the second semiconductor pattern SM2, the first cladding CL1, the second bonding member BD2, and the second cladding CL2.

A silicon photonic integrated circuit may be formed on the first semiconductor pattern SM1. The first semiconductor pattern SM1 may include silicon and a P-type silicon semiconductor. The first filter-unit semiconductor FSM1 (see FIG. 2B) and the first modulation-unit semiconductor MSM1 (see FIG. 4B) may each be a part of the first

### Semiconductor Pattern Sm1.

The first bonding member BD1 may include an insulating material. The first bonding member BD1 may bond the first semiconductor pattern SM1 to the second semiconductor pattern SM2. The filter-unit FIN (see FIG. 2B) and the modulator insulator MIN (see FIG. 4B) may each be a part of the first bonding member BD1. For example, the insulating material may include at least any one of SiO2, Al2O3, Y2O3, and HfO2. However, these are merely examples, and the insulating material of the present disclosure is not limited thereto. A material having a high dielectric constant is sufficient as the insulating material of the present disclosure.

The second semiconductor pattern SM2 may include an N-type group III-V compound semiconductor. For example, the group III-V compound semiconductor may include at least any one of InP, InGaAsP, and InGaAlAs. The second filter-unit semiconductor FSM2 (see FIG. 2B) the second modulation-unit semiconductor MSM2 (see FIG. 4B), and the first optical-gain-unit semiconductor LSM1 may each be a part of the second semiconductor pattern SM2. The second filter-unit semiconductor FSM2 (see FIG. 2B), the second modulation-unit semiconductor MSM2 (see FIG. 4B), and the first optical-gain-unit semiconductor LSM1 may be formed through a same process.

The first cladding CL1 may have a low refractive index and focus light. The first cladding CL1 may cover the second filter-unit semiconductor FSM2 (see FIG. 2B), and the second modulation-unit semiconductor MSM2 (see FIG. 4B). For example, the first cladding CL1 may include, for example, SiO2, or Polymer.

The second bonding member BD2 may be disposed on the first cladding CL1. The second bonding member BD2 may include an insulating material. For example, the insulating material may include at least any one of SiO2, Al2O3, Y2O3, HfO2, and Polymer.

The second cladding CL2 may have a low refractive index and focus light. The second cladding CL2 may cover the second bonding member BD2 and the first optical-gain-unit semiconductor LSM1 (see FIG. 8). For example, the second cladding CL2 may include, for example, SiO2, or Polymer.

Referring to FIG. 10, the phase modulation unit RM and the optical gain unit LD may be disposed on different layers in one embodiment of the present disclosure. Particularly, the first optical-gain-unit semiconductor LSM1 may be disposed on a different layer from at least any one of the second modulation-unit semiconductor MSM2 and the second filter-unit semiconductor FSM2. Particularly, at least any one of the second modulation-unit semiconductor MSM2 and the second filter-unit semiconductor FSM2 may be disposed below the bonding member BD2, and the first optical-gain-unit semiconductor LSM1 may be disposed above the second bonding member BD2.

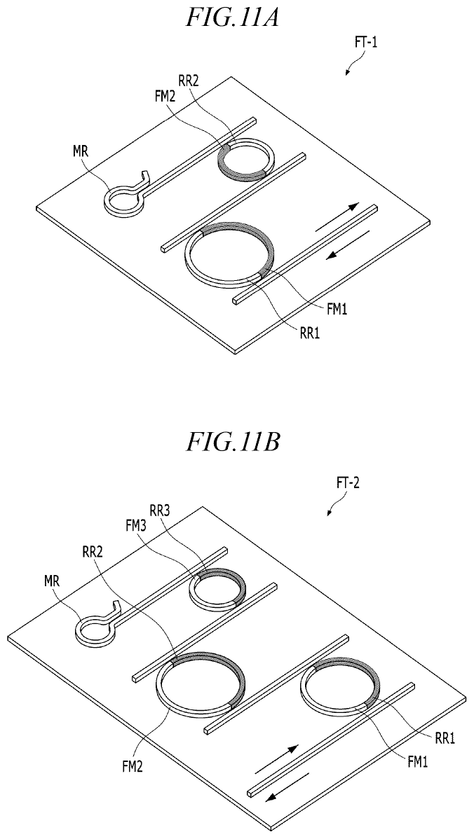

FIG. 11A and FIG. 11B are exemplary illustrations of filter units FT-1, FT-2 according to one embodiment of the present disclosure.

In one embodiment of the present disclosure, the filter unit FT-1, FT-2 may further include a mirror MR. The first ring resonator RR1 may be provided in a plurality.

The mirror MR may reflect at least a portion of received light. The ring resonator RR may be disposed between the mirror MR and the optical gain unit LD.

Referring to FIG. 11A, the filter unit FT-1 may include a first ring resonator RR1, a second ring resonator RR2, and a mirror MR. For example, the mirror MR may be a loop mirror.

The first ring resonator RR1 may include a first filter-unit modulator FM1.

The second ring resonator RR2 may include a second filter-unit modulator FM2.

The first ring resonator RR1 and the second ring resonator RR2 may have different resonant frequencies from each other.

The filter unit FT-1 may reflect light having a first resonant frequency FR1 (see FIG. 1C), light having a second resonant frequency FR2 (see FIG. 1C), and light having a third resonant frequency FR3 (see FIG. 1C) in a direction toward the optical gain unit LD. The optical gain unit LD may amplify at least any one of the light having a first resonant frequency FR1 (see FIG. 1C), the light having a second resonant frequency FR2 (see FIG. 1C), and the light having a third resonant frequency FR3 (see FIG. 1C). For example, the optical gain unit LD may amplify the light having a second resonant frequency FR2.

Referring to FIG. 11B, the filter unit FT-2 may include a first ring resonator RR1, a second ring resonator RR2, a third ring resonator RR3, and a mirror MR. For example, the mirror MR may be a loop mirror.

The first ring resonator RR1 may include a first filter unit modulator FM1.

The second ring resonator RR2 may include a second filter unit modulator FM2.

The third ring resonator RR3 may include a third filter unit modulator FM3.

The first ring resonator RR1, the second ring resonator RR2, and the third ring resonator RR3 may have different resonant frequencies from one another.

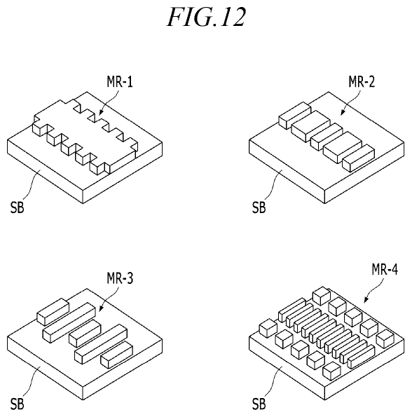

FIG. 12 is an exemplary illustration of a mirror MR-1, MR-2, MR-3, MR-4 according to one embodiment of the present disclosure.

Referring to FIG. 12, the mirror MR-1, MR-2, MR-3, MR-4 in one embodiment of the present disclosure may be a Bragg Grating mirror. The Bragg Grating mirror may reflect light having a certain wavelength through Bragg Diffraction.

In one embodiment of the present disclosure, the filter unit FT-3, FT-4 may further include a multimode interferometer MMI. The multimode interferometer MMI may split received light or combine received light. The multimode interferometer MMI may be disposed between the ring resonator RR and the optical gain unit LD.

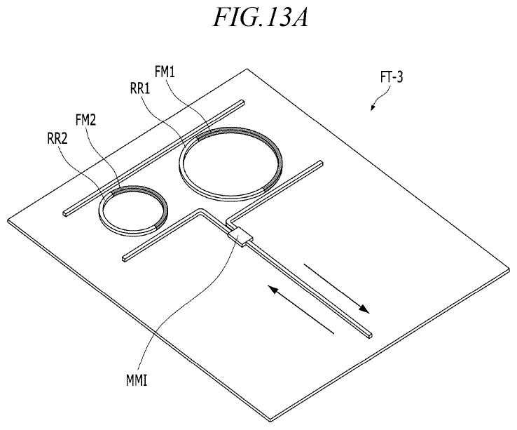

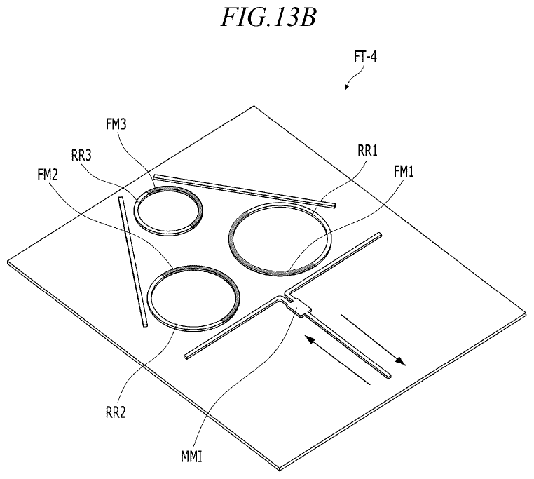

FIG. 13A and FIG. 13B are exemplary illustrations of shapes of filter units FT-3, FT-4 according to one embodiment of the present disclosure.

Referring to FIG. 13A, the filter unit FT-3 may include a first ring resonator RR1, a second ring resonator RR2, and a multimode interferometer MMI.

The first ring resonator RR1 may include a first filter-unit modulator FM1.

The second ring resonator RR2 may include a second filter-unit modulator FM2.

The first ring resonator RR1 and the second ring resonator RR2 may have different resonant frequencies.

Referring to FIG. 13B, the filter unit FT-4 may include a first ring resonator RR1, a second ring resonator RR2, and a third ring resonator RR3, and a multimode interferometer MMi.

The first ring resonator RR1 may include a first filter-unit modulator FM1.

The second ring resonator RR2 may include a second filter-unit modulator FM2.

The third ring resonator RR3 may include a third filter-unit modulator FM3.

The first ring resonator RR1, the second ring resonator RR2, and the third ring resonator RR3 may have different resonant frequencies from one another.

In one embodiment of the present disclosure, the optical gain unit LD may include a semiconductor optical amplifier. The semiconductor optical amplifier may be a semiconductor device configured to amplify an optical signal. For example, the semiconductor optical amplifier may have a Multi-quantum Well structure including at least any one of InP and InGa AlAs, or a Quantum Dot structure including InGaAlAs.

In one embodiment of the present disclosure, the semiconductor optical amplifier may have an Adiabatic Taper structure. For example, the Adiabatic Taper structure may include a single step or a double step.

While certain embodiments of the present disclosure have been described above, anyone ordinarily skilled in the art to which the present disclosure pertains shall appreciate that there may be a variety of modifications and permutations of the present disclosure without departing from the technical ideas and scopes of the present disclosure that are defined in the appended claims. Moreover, it shall be appreciated that the disclosed embodiments are not intended to restrict the present disclosure thereto and that every technical idea within the appended claims and their equivalents is interpreted to be included in the scope of the present disclosure.

What is claimed is:

1. A wavelength tunable laser based on a silicon semiconductor and a group III-V compound semiconductor, comprising:
a base member;
a optical gain unit disposed on the base member, and configured to emit or amplify light; and
a filter unit disposed on the base member, comprising a ring resonator having a predetermined resonant frequency, and configured to reflect light having the predetermined resonant frequency among received light in a direction toward the optical gain unit,
wherein the ring resonator comprises a filter-unit modulator configured to modify the predetermined resonant frequency, and
wherein the filter-unit modulator comprises:
a first filter-unit semiconductor comprising a P-type silicon semiconductor;
a second filter-unit semiconductor disposed above the first filter-unit semiconductor and comprising an N-type group III-V compound semiconductor; and
a filter-unit insulator disposed between the first filter-unit semiconductor and the second filter-unit semiconductor and comprising an insulating material.

2. The wavelength tunable laser based on a silicon semiconductor and a group III-V compound semiconductor of claim 1, further comprising:
a reflection unit disposed on the base member,
wherein the reflection unit is configured to reflect at least a portion of received light in a direction towards the optical gain unit and output a remaining portion to outside, and
wherein the optical gain unit is disposed between the reflection unit and the filter unit.

3. The wavelength tunable laser based on a silicon semiconductor and a group III-V compound semiconductor of claim 2, further comprising:
a phase modulation unit disposed on the base member,
wherein an optical path, through which light propagates, is defined between the filter unit and the reflection unit, and the phase modulation unit is configured to modify a resonant frequency of the optical path.

4. The wavelength tunable laser based on a silicon semiconductor and a group III-V compound semiconductor of claim 3,
wherein the phase modulation unit is disposed between the optical gain unit and the filter unit, and
wherein the phase modulation unit comprises:
a first modulation-unit semiconductor comprising a P-type silicon semiconductor;
a second modulation-unit semiconductor disposed above the first modulation-unit semiconductor, and comprising an N-type group III-V compound semiconductor; and
a modulation-unit insulator disposed between the first modulation-unit semiconductor and the second modulation-unit semiconductor and comprising an insulating material.

5. The wavelength tunable laser based on a silicon semiconductor and a group III-V compound semiconductor of claim 4,
wherein the filter-unit modulator further comprises a first filter-unit electrode making contact with the first filter-unit semiconductor, and a second filter-unit electrode making contact with the second filter-unit semiconductor, and
wherein the phase modulation unit further comprises a first modulation-unit electrode making contact with the first modulation-unit semiconductor, and a second modulation-unit electrode making contact with the second modulation-unit semiconductor.

6. The wavelength tunable laser based on a silicon semiconductor and a group III-V compound semiconductor of claim 5,
wherein the optical gain unit comprises:
a first optical-gain-unit semiconductor comprising an N-type group III-V compound semiconductor;
a second optical-gain-unit semiconductor facing the first optical-gain-unit semiconductor and comprising a P-type silicon semiconductor; and
a light-emission layer disposed between the first optical-gain-unit semiconductor and the second optical-gain-unit semiconductor and comprising a light-emission layer configured to emit light, and
wherein the first optical-gain-unit semiconductor is disposed on a layer different from at least one of the second filter-unit semiconductor and the second modulation-unit semiconductor.

7. The wavelength tunable laser based on a silicon semiconductor and a group III-V compound semiconductor of claim 6, further comprising:
a bonding member comprising an insulating material,
wherein at least any one of the second filter-unit semiconductor and the second modulation-unit semiconductor is disposed below the bonding member, and the first optical-gain-unit semiconductor is disposed above the bonding member.

8. The wavelength tunable laser based on a silicon semiconductor and a group III-V compound semiconductor of claim 7,
wherein the base member comprises SiO2,
wherein the group III-V compound semiconductor comprises at least any one of InP, InGaAsP, and InGaAlAs, and
wherein each of the first filter-unit electrode, the second filter-unit electrode, the first modulation-unit electrode, and the second modulation-unit electrode comprises at least any one of Pt, Ti, Au, TiN, Al, W, Ag, Cu, Au, Ge, and Ni.

9. The wavelength tunable laser based on a silicon semiconductor and a group III-V compound semiconductor of claim 7,
wherein the reflection unit has a first area and a second area defined therein, and
wherein a thickness of the reflection unit measured in the first area is greater than a thickness of the reflection unit measured in the second area.

10. The wavelength tunable laser based on a silicon semiconductor and a group III-V compound semiconductor of claim 7,
wherein the ring resonator is provided in a plurality,
wherein the plurality of ring resonators have different resonant frequencies,
wherein the filter unit comprises at least any one of a multimode interferometer and a mirror, and
wherein the multimode interferometer is configured to split received light or combine received light, and the mirror is configured to reflect at least a portion of received light.

11. A wavelength tunable laser based on a silicon semiconductor and a group III-V compound semiconductor, comprising:
a base member;
a optical gain unit disposed on the base member, and configured to emit or amplify light;
a filter unit disposed on the base member, comprising a ring resonator having a predetermined resonant frequency, and configured to reflect light having the predetermined resonant frequency among received light in a direction toward the optical gain unit; and
a reflection unit disposed on the base member and configured to reflect at least a portion of received light in a direction toward the optical gain unit and output a remaining portion to outside,
wherein the ring resonator comprises a filter-unit modulator configured to modify the predetermined resonant frequency, and having a Semiconductor Insulator Semiconductor (SIS) structure, in which an insulator is disposed between two semiconductors.

12. The wavelength tunable laser based on a silicon semiconductor and a group III-V compound semiconductor of claim 11, further comprising:
a phase modulation unit disposed on the base member,
wherein an optical path, through which light propagates, is defined between the filter unit and the reflection unit, and the phase modulation unit is configured to modify a resonant frequency of the optical path.

13. The wavelength tunable laser based on a silicon semiconductor and a group III-V compound semiconductor of claim 12,
wherein the filter-unit modulator comprises:
a first filter-unit semiconductor comprising a P-type silicon semiconductor;
a second filter-unit semiconductor disposed above the first filter-unit semiconductor and comprising an N-type group III-V compound semiconductor; and
a filter-unit insulator disposed between the first filter-unit semiconductor and the second filter-unit semiconductor, and comprising an insulating material.

14. The wavelength tunable laser based on a silicon semiconductor and a group III-V compound semiconductor of claim 13,
wherein the phase modulation unit comprises:
a first modulation-unit semiconductor comprising a P-type silicon semiconductor;
a second modulation-unit semiconductor disposed above the first modulation-unit semiconductor and comprising an N-type group III-V compound semiconductor; and
a modulation-unit insulator disposed between the first modulation-unit semiconductor and the second modulation-unit semiconductor and comprising an insulating material.

15. The wavelength tunable laser based on a silicon semiconductor and a group III-V compound semiconductor of claim 14,
wherein the filter-unit modulator further comprises a first filter-unit electrode making contact with the first filter-unit semiconductor, and a second filter-unit electrode making contact with the second filter-unit semiconductor, and
wherein the phase modulation unit further comprises a first modulation-unit electrode making contact with the first modulation-unit semiconductor, and a second modulation-unit electrode making contact with the second modulation-unit semiconductor.

16. The wavelength tunable laser based on a silicon semiconductor and a group III-V compound semiconductor of claim 15,
wherein the optical gain unit comprises:
a first optical-gain-unit semiconductor comprising an N-type group III-V compound semiconductor;
a second optical-gain-unit semiconductor facing the first optical-gain-unit semiconductor, and comprising a P-type silicon semiconductor; and
a light-emission layer disposed between the first optical-gain-unit semiconductor and the second optical-gain-unit semiconductor, and configured to emit light, and
wherein the first optical-gain-unit semiconductor is disposed on a layer different from at least any one of the second filter-unit semiconductor and the second modulation-unit semiconductor.

17. The wavelength tunable laser based on a silicon semiconductor and a group III-V compound semiconductor of claim 16, further comprising:
a bonding member comprising an insulating material,
wherein at least one of the second filter-unit semiconductor and the second modulation-unit semiconductor is disposed below the bonding member, and the first optical-gain-unit semiconductor is disposed above the bonding member.

18. The wavelength tunable laser based on a silicon semiconductor and a group III-V compound semiconductor of claim 17,
wherein the base member comprises SiO2,
wherein the group III-V compound semiconductor comprises at least any one of InP, InGaAsP, and InGaAlAs, and
wherein each of the first filter-unit electrode, the second filter-unit electrode, the first modulation-unit electrode, and the second modulation-unit electrode comprises at least any one of Pt, Ti, Au, TiN, Al, W, Ag, Cu, Au, Ge, and Ni.

19. The wavelength tunable laser based on a silicon semiconductor and a group III-V compound semiconductor of claim 17,
wherein the reflection unit has a first area and a second area defined therein, and
wherein a thickness of the reflection unit measured in the first area is greater than a thickness of the reflection unit measured in the second area.

20. The wavelength tunable laser based on a silicon semiconductor and a group III-V compound semiconductor of claim 17,
wherein the ring resonator is provided in a plurality,
wherein the plurality of ring resonators have different resonant frequencies from one another,
wherein the filter unit further comprises at least any one of a multimode interferometer and a mirror, and
wherein the multimode interferometer is configured to split received light or combine received light, and the mirror is configured to reflect at least a portion of received light.
